(19) United States
(12) Patent Application Publication
(10) Pub. No.: US 2012/0007206 A1
(43) Pub. Date: Jan. 12, 2012

(54) Structures and methods for forming schottky diodes on a p-substrate or a bottom anode schottky diode

(76) Inventors: Anup Bhalla, Santa Clara, CA (US); Sik K. Lui, Sunnyvale, CA (US); Yi Su, Sunnyvale, CA (US)

(21) Appl. No.: 13/199,264

(22) Filed: Aug. 23, 2011

Related U.S. Application Data
(62) Division of application No. 11/890,851, filed on Aug. 8, 2007.

(51) Int. Cl. H01L 29/47; H01L 21/329

(52) U.S. Cl. 257/472; 438/572; 257/E21.359; 257/E29.148

(57) ABSTRACT

This invention discloses bottom-anode Schottky (BAS) device supported on a semiconductor substrate having a bottom surface functioning as an anode electrode with an epitaxial layer has a same doped conductivity as said anode electrode overlying the anode electrode. The BAS device further includes an Schottky contact metal disposed in a plurality of trenches and covering a top surface of the semiconductor substrate between the trenches. The BAS device further includes a plurality of doped JBS regions disposed on sidewalls and below a bottom surface of the trenches doped with an opposite conductivity type from the anode electrode constituting a junction barrier Schottky (JBS) with the epitaxial layer disposed between the plurality of doped JBS regions. The BAS device further includes an ultra-shallow Shannon implant layer disposed immediate below the Schottky contact metal in the epitaxial layer between the plurality of doped JBS regions.

This patent application is a Divisional Application and claims the Priority Date of a co-pending application Ser. No. 11/890,851 filed on Aug. 8, 2007 by common Inventors of this Application. The Disclosures made in the patent application Ser. No. 11/890,851 are hereby incorporated by reference.

### BACKGROUND OF THE INVENTION

1. Field of the Invention

The invention relates generally to Schottky diode devices. More particularly, this invention relates to a device configuration and method of manufacturing Schottky diodes on a P-substrate or forming Schottky diodes with a bottom-anode for multiple applications.

2. Description of the Prior Art

Conventional Schottky diodes with a vertical structure formed on an N-type substrate that have the cathode disposed at the bottom of a substrate are limited by several difficulties of application. As a high voltage bias is applied to the substrate, the Schottky diodes formed on an N-substrate with cathode at the bottom of the substrate are not compatible with some assembly configurations. Furthermore, for high voltage devices, such device configuration requires an electrical isolation of the heat sink where the die is mounted which causes limitations on heat dissipation and adds to complications to system designs when the vertical Schottky diodes supported on an N-type substrate are provided with the cathode disposed at the bottom of a substrate.

Different types of vertical Schottky diodes have been disclosed. FIG. 1A shows a cross sectional view of a Junction Barrier controlled Schottky (JBS) diode formed on the top of an N-type substrate and FIG. 1B shows an alternate Schottky diode implemented as a Trench MOS-Barrier controlled Schottky (TMBS) diode on the bottom of a N-type substrate. In either of the Schottky diodes, the Schottky barrier is shielded from the high voltage by depletion regions in the vertical low-doped cathode N− region. FIGS. 1C and 1D show alternate JBS diodes in U.S. Pat. No. 4,134,123 with the P+ regions pinching off the cathode from the top anode region. However, the Schottky diodes with a vertical configuration and the cathode on the bottom as shown in these disclosures are still limited by the difficulties discussed above for some practical applications, especially when applied to portable devices that require small package with multi functions to reduce component count and space. Specifically, for power boost converter application the anode of an Schottky diode is connected to the Drain of a MOSFET, which is usually at the bottom of the MOSFET die. It is desirable to co-package the Schottky diode into the MOSFET package to reduce anode parasitic inductance; it is necessary to have two separate die pads for mounting the MOSFET and the Schottky separately. This increases the assembly complexity and cost.

Therefore, a need still exists in the art of device design and manufacture of Schottky diodes to provide new device configurations and manufacturing method to provide new and improved Schottky diodes with anode on the bottom of the substrate such that the above discussed problems and limitations can be resolved.

### SUMMARY OF THE PRESENT INVENTION

It is therefore an aspect of the present invention to provide a new and improved Schottky diode implemented with a Schottky barrier controlling layer disposed immediate below the Schottky barrier metal to control the Schottky barrier height and width for improving the performance of Schottky diode.

It is another aspect of the present invention to provide a new and improved bottom-anode Schottky (BAS) diode by forming a low energy shallow N-implant whereby the barrier height and width of the Schottky may be adjusted by using a low energy shallow implant to allow for control over the leakage current versus the forward voltage tradeoffs.

It is another aspect of the present invention to provide improved bottom-anode Schottky diode device implemented with an increased aspect ratio represent by D/W, i.e., the depth of the doped N+ regions functioning as JBS regions, versus the width of the Schottky contact regions such that a reverse leakage current is reduced.

It is another aspect of the present invention to provide improved bottom-anode Schottky diode device implemented with placing Schottky contact metal in trenches with doped regions implanted surrounding sidewalls and below bottom surface of trenches to further increasing the aspect ratio between the depth of the N+ doped region functioning as JBS regions, versus the width of Schottky contact regions such that a reverse leakage current is further reduced.

It is another aspect of the present invention to provide improved bottom-anode Schottky diode device by application of a thin layer of lightly doped narrow bandgap material disposed immediate below the Schottky barrier metal for controlling the barrier height and width through the control of layer thickness, and composition.

Briefly in a preferred embodiment this invention discloses a bottom-anode Schottky (BAS) device supported on a semiconductor substrate having a bottom surface functioning as an anode electrode with an epitaxial layer having a same conductivity type overlying the substrate. The BAS device further includes a plurality of doped regions disposed near a top surface of the epitaxial layer doped with an opposite conductivity type from the substrate constituting a junction barrier Schottky (JBS) with the epitaxial layer disposed between the plurality of doped JBS regions. The BAS device further includes an Schottky barrier metal disposed on top of the semiconductor constituting an ohmic contact to the plurality of doped JBS regions and Schottky contact to the epitaxial layer between the plurality of doped JBS regions. The BAS device further includes an Schottky barrier-controlling layer disposed immediate below the Schottky contact metal in the epitaxial layer between the plurality of doped JBS regions. In an exemplary embodiment, the semiconductor substrate is a P-type substrate and the plurality of doped JBS regions includes N-type doped JBS regions and the Schottky barrier controlling layer includes an ultra-shallow N-Shannon implant layer. In another exemplary embodiment, a barrier height of the Schottky contact is adjusted by a low energy shallow implant of the N-Shannon layer to allow a control of the leakage current versus the forward voltage tradeoffs. In another exemplary embodiment, a minority carrier injection from the doped JBS regions is suppressed when a forward voltage VF is below approximately 0.7 volts. In another exemplary embodiment, a majority carrier from the anode electrode having a reduced barrier to reach the Schottky contact metal constituting a cathode electrode. In another exemplary embodiment, the ultra-shallow N-Shannon implanted layer includes an arsenic implanted layer. In another exemplary embodiment, the Schottky barrier controlling layer comprising a lightly doped narrow bandgap material. In another exemplary embodiment, the height and width of an Schottky barrier are controlled by adjusting composition and layer thickness of narrow bandgap material. In another exemplary embodiment, narrow bandgap material comprising silicon rich SiGe with a layer thickness in the range from 100 Å to 1000 Å.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A and 1B are cross sectional views for showing the typical junction barrier Schottky (JBS) diodes and trench MOS barrier Schottky (TMBS) of the conventional Schottky diodes.

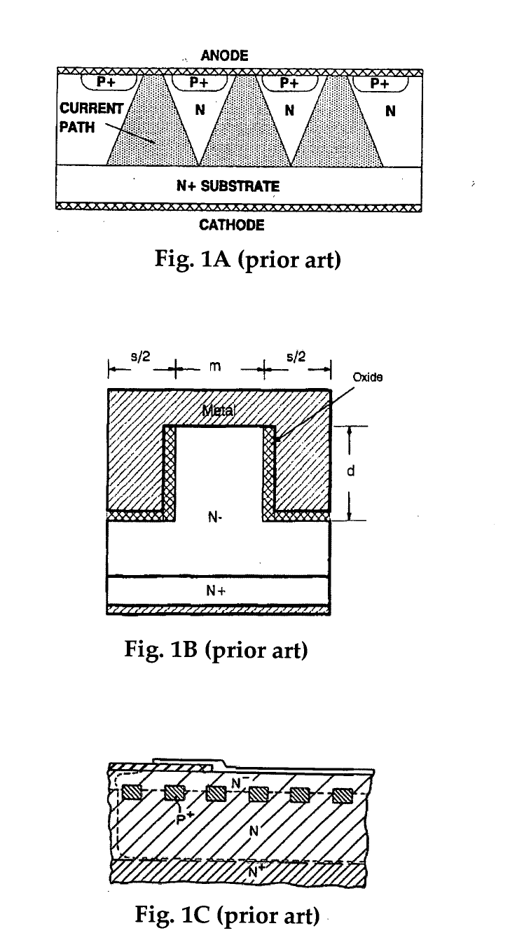

FIGS. 1C and 1D are cross sectional views of Junction Barrier Schottky diodes with top anode configuration.

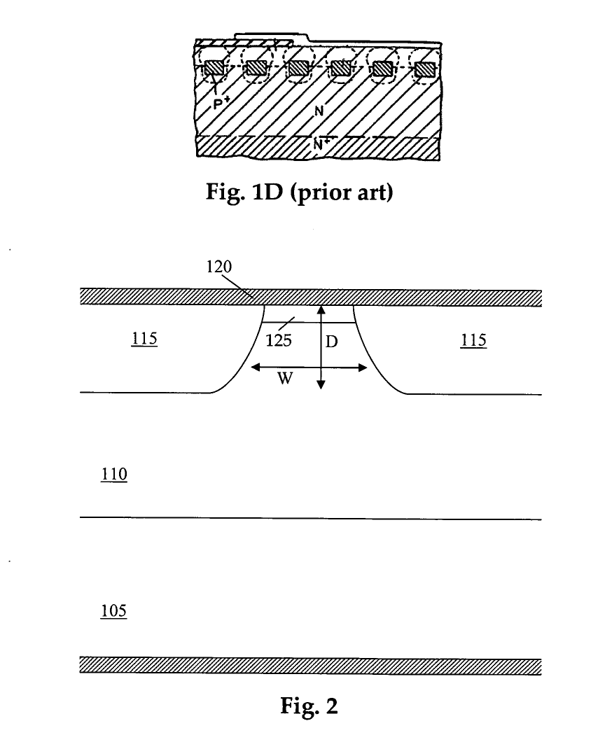

FIG. 2 is a cross sectional view of a bottom anode Schottky (BAS) diode as an exemplary embodiment of this invention.

FIG. 3 is a cross sectional view of an alternate embodiment of the Schottky devices this invention.

FIG. 4A-4C are the cross sectional views of process for an alternate embodiments of an Schottky device of this invention.

FIG. 5 is the affect of band diagram of SiGe thin layer on the Si substrate.

### DETAILED DESCRIPTION OF THE METHOD

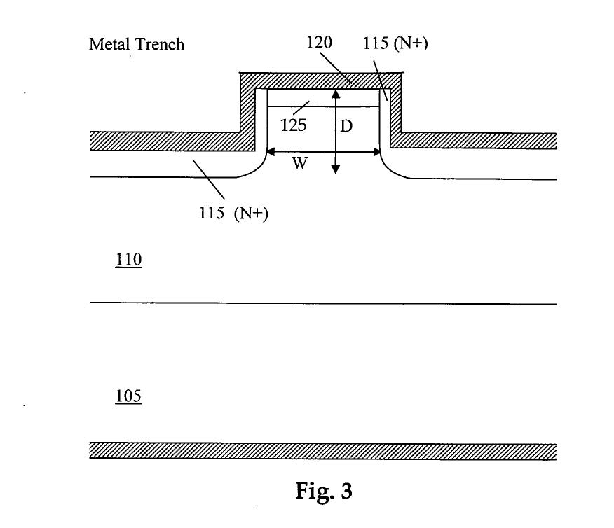

Referring to FIG. 2 for a side cross sectional view of a bottom anode Schottky (BAS) diode device formed on a P+ substrate and the process of its formation according to this invention. The BAS diode device is supported on a P+ substrate 105 functioning as a bottom anode electrode. A layer of P− epitaxial layer 110 is supported on top of the substrate 105. The bottom anode Schottky diode further includes N+ implanted regions 115 to form junctions in the P epi layer. In one embodiment, a first N implant of Arsenic is carried out with a mask (not shown) with a dosage of 1E15 at the energy level of 60 KeV; in another embodiment, a second N implant follows the first N implant with Phosphorus ions at 2E12 and 300 KeV then followed with a drive-in diffusion process at a temperature between 900-1100 degree ° C. for about 30 minutes. An ultra-shallow N− Shannon implant layer 125 is formed by N type implantation with low energy. In an exemplary embodiment, the N− Shannon implant layer 125 is implanted with arsenic ions at an energy of about 10 keV with an implanting dosage of about 5×10¹²/cm² and the layer is formed with a rapid thermal annealing process (RTP) at about 900° C. for 30 seconds.

A Schottky barrier metal layer 120 is deposited on top of the epitaxial layer 110 that forms ohmic contact to the N+ regions 115 and forms Schottky contact with ultra-shallow N− Shannon implant region 125.

The dopant concentration of ultra-shallow layer 125 and the layer depth are controlled such that under zero bias condition, the charge carriers are depleted and dopant concentration is controlled to adjust the Schottky diode forward voltage. The Schottky barrier height is thus adjusted without affecting the reversed characteristic of the Schottky diode, which is determined by the dopant concentration and depth of P-epitaxial layer 110.

With the ultra-shallow light N− Shannon layer 125, a junction is formed near the top surface that is depleted by the built-in potential of the Schottky. Compared with conventional PN junctions, the holes from the anode now have a reduced barrier to reach the cathode. The minority carrier injection from the N+ regions 115 is suppressed as long as the forward voltage VF is below the intrinsic PN junction forward voltage of 0.7 volts. Improvement of reverse performance is further achieved because in the meantime, the N+ regions 115 shield the Schottky area in the condition of reverse bias, thus attaining lower leakage current. The bottom anode Schottky diode has several advantages. The ultra-shallow light N− Shannon layer 125 has the effect of pulling back the body regions right before the metal deposition. More compact and reduced area requirement is achieved for the Schottky diode. Furthermore, the barrier height of the Schottky may be adjusted by a low energy shallow implant of the N− Shannon layer 125 to allow a control of the leakage current versus the forward voltage tradeoffs. For the purpose of further reducing the leakage current, it is beneficial to have a large aspect ratio of D/W as shown in FIG. 2. To reduce conducting resistance and improve current handling capability, it is desirable to have a large Schottky contact area, meaning large W. The only adjustable parameters are the depth of N+ implant. High energy multi implant and overtime diffusion at elevated temperature may help increase the depth D. Unfortunately the high temperature overtime diffusion also inevitably reduces W due to lateral diffusion, which is undesirable.

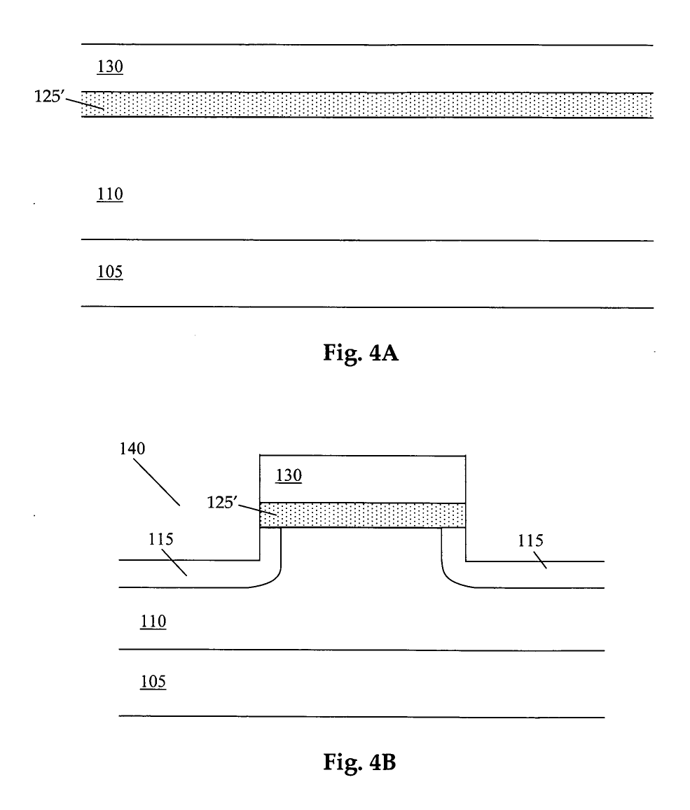

FIG. 3 shows an alternative embodiment where trenches are etched into the epitaxial layer 110 and N+ regions 115 are formed by implantation through the sidewall and the bottom of trenches. In one embodiment, N+ regions 115 are formed by a first implant of Arsenic dopant with 2E15 at energy level of 60 KeV and a second implant of Phosphorous dopant with 2E13 at energy level of 180 KeV. Both implants are carried out with 7 degree angle with four rotation to ensure all sides of trench walls are covered, followed by a diffusion process at 900 C for 30 minutes. The processes effectively improve the D/W aspect ration as the depth of trench extends the N+ regions 115 to a deeper depth without causing additional undesirable lateral diffusion. By increasing the trench depth from 0.2 to 1 um, the reverse current can be reduced by more than 97% while the forward voltage remains essentially the same.

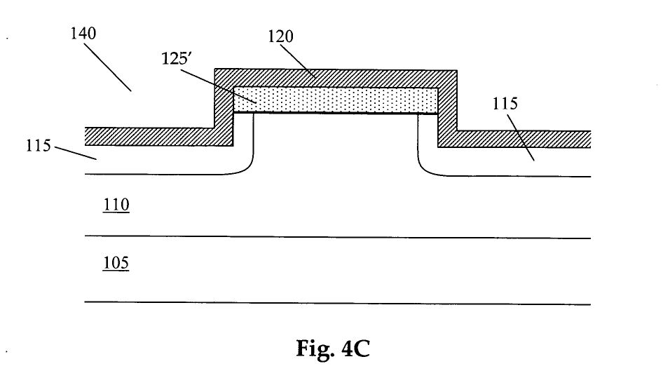

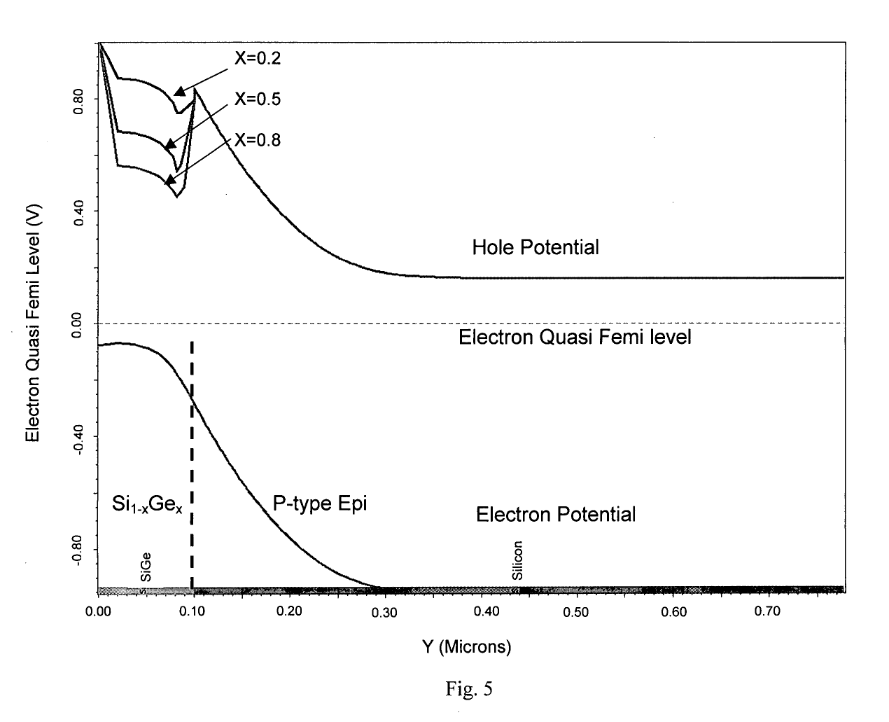

The purpose of controlling the barrier height and width of the Schottky may also be realized by the application of a thin layer of narrow bandgap material. Referring to FIGS. 4A to 4C for the side cross sectional views of the process of an Schottky diode devices as alternate embodiments of this invention. In FIG. 4A a narrow bandgap material such as SiGe is deposited by CVD to form a layer 125′ on the top surface of a P− epitaxial layer 110 which is supported on top of the P+ substrate 105 functioning as the anode of Schottky diode. The thickness of narrow bandgap material layer could be in the range from 100 Å to 1000 Å. In one embodiment, layer 125′ comprises a 200 Å silicon rich SiGe. In another embodiment the silicon rich SiGe layer comprises 80% Si and 20% Ge. In another embodiment layer 125′ is in-situ doped with N type dopant at a concentration between 2E17 to 2E18/cm³. A low temperature oxide layer 130 is then deposited over the narrow bandgap layer 125′. In FIG. 4B, oxide layer 130 is patterned by a mask (not shown) to form a hard mask for dry etching trenches 140 into the epitaxial layer 110. Hard mask 130 protects the portion of narrow bandgap layer 125′ underneath during the dry etching process and the N+ implantation which forms N+ regions 115. In FIG. 4C, a Schottky metal layer 120 is deposited after the removal of hard mask 130 and a Schottky diode is formed similar to FIG. 3 except that the ultra-shallow light N− Shannon layer 125 is replaced by a thin layer of doped narrow bandgap material 125′. By controlling the composition and the thickness of narrow bandgap layer 125′, the barrier height and width of the Schottky may be adjusted. FIG. 5 shows the hole potential varies with the composition parameter x in Si₁₋ₓGeₓ. To avoid hole trapping at the SiGe layer surface close to the Si it is preferable to have a Si rich SiGe layer. The thickness of SiGe layer also affects the width of the Schottky barrier.

According to above drawings and descriptions, this invention also discloses a semiconductor power device supported on a semiconductor substrate of a first conductivity type having a bottom layer functioning as a bottom anode electrode and an epitaxial layer having a same conductivity type overlying the bottom layer. In an exemplary embodiment, the shallow layer of doped region further includes a shallow doped region with ions of the first conductivity type with an ion concentration higher than the epitaxial layer. In another exemplary embodiment, the shallow layer of doped region further includes a shallow Shannon doped region with ions of the second conductivity type for adjusting a barrier height of the Schottky diodes. In another exemplary embodiment, the power device further includes a layer of narrow bandgap metal disposed immediately below an Schottky barrier metal layer over the epitaxial layer to form a low forward voltage junction to function as an Schottky.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

We claim:

1. A bottom-anode Schottky (BAS) device supported on a semiconductor substrate having a bottom surface functioning as an anode electrode with an epitaxial layer overlying said anode electrode having a same doped conductivity as said anode electrode, said BAS device further comprising:
a Schottky barrier metal disposed in a plurality of trenches and covering a top surface of said semiconductor substrate between said trenches; and
a plurality of doped JBS regions disposed on sidewalls and below a bottom surface of said trenches doped with an opposite conductivity type from said anode electrode constituting a junction barrier controlled Schottky (JBS) with said epitaxial layer disposed between said plurality of doped JBS regions.

2. The BAS device of claim 1 further comprising:
an Schottky barrier-controlling layer disposed immediate below the Schottky barrier metal in said epitaxial layer between said plurality of doped JBS regions.

3. The BAS device of claim 1 further comprising:
said trenches filled with said Schottky barrier metal having a depth of substantially between 0.2 to 1.0 um.

4. The BAS device of claim 1 further comprising:
said plurality of doped JBS regions disposed around said sidewalls and below a bottom surface of said trenches further comprising first JBS region doped with arsenic ions and a second JBS region doped with phosphorous ions with a higher energy than said arsenic ions.

5. The BAS device of claim 1 wherein:
an ultra-shallow Shannon implant layer disposed immediate below the Schottky barrier metal in said epitaxial layer between said plurality of doped JBS regions.

6. The BAS device of claim 1 further comprising:
a narrow bandgap layer disposed immediate below the Schottky barrier metal in said epitaxial layer between said plurality of doped JBS regions.

7. The BAS device of claim 1 further comprising:
a narrow bandgap layer composed of SiGe disposed immediate below the Schottky barrier metal in said epitaxial layer between said plurality of doped JBS regions.

8. The BAS device of claim 1 further comprising:
a narrow bandgap layer of a layer thickness in a range from 100 Å to 1000 Å disposed immediate below the Schottky barrier metal in said epitaxial layer between said plurality of doped JBS regions.

9. The BAS device of claim 1 further comprising:
a narrow bandgap layer composed of SiGe having 80% Si and 20% Ge disposed immediate below the Schottky barrier metal in said epitaxial layer between said plurality of doped JBS regions.

10. The BAS device of claim 1 further comprising:
a narrow bandgap layer comprising an in-situ doped N-type dopant layer having a dopant concentration between 2E17 to 2E18/cm³ disposed immediate below the Schottky barrier metal in a P-type epitaxial layer between said plurality of doped JBS regions.

11. The BAS device of claim 1 further comprising:
a narrow bandgap layer comprising a silicon rich SiGe having a layer thickness approximately 200 Å disposed immediate below the Schottky contact metal in said epitaxial layer between said plurality of doped JBS regions.

12. A method for manufacturing a bottom-anode Schottky (BAS) device supported on a semiconductor substrate having a bottom surface functioning as an anode electrode with an epitaxial layer overlying said anode electrode having a same doped conductivity as said anode electrode, said BAS device further comprising:
opening a plurality of trenches and implanting a plurality of doped JBS regions on sidewalls and below a bottom surface of said trenches with a dopant of opposite conductivity type from said anode electrode to function as a junction barrier Schottky (JBS) with said epitaxial layer disposed between said plurality of doped JBS regions; and
depositing an Schottky barrier metal to cover the sidewalls and bottom surface of said trenches and cover a top surface of said semiconductor substrate between said trenches.

13. The method of claim 12 further comprising:
implanting an ultra-shallow Shannon layer disposed immediate below the Schottky contact metal in said epitaxial layer between said plurality of doped JBS regions.

14. The method of claim 12 wherein:
said step of opening said trenches further includes a step of opening said trenches with a depth of substantially between 0.2 to 1.0 um for covering with said Schottky barrier metal.

15. The method of claim 12 wherein:
said step of implanting said plurality of doped JBS regions around said sidewalls and below a bottom surface of said trenches further comprising a step of implanting a first JBS region with arsenic ions and implanting a second JBS region doped phosphorous ions with a higher energy than said arsenic ions.

16. The method of claim 12 further comprising:
depositing a narrow bandgap layer immediate below the Schottky contact metal in said epitaxial layer between said plurality of doped JBS regions.

17. The method of claim 12 further comprising:
depositing a narrow bandgap layer composed of SiGe immediate below the Schottky contact metal in said epitaxial layer between said plurality of doped JBS regions.

18. The method of claim 12 further comprising:
depositing a narrow bandgap layer of a layer thickness in a range from 100 Å to 1000 Å immediate below the Schottky contact metal in said epitaxial layer between said plurality of doped JBS regions.

19. The method of claim 12 further comprising:
depositing a narrow bandgap layer composed of SiGe having 80% Si and 20% Ge immediate below the Schottky contact metal in said epitaxial layer between said plurality of doped JBS regions.

20. The method of claim 12 further comprising:
depositing a narrow bandgap layer comprising an in-situ doped N-type dopant layer having a dopant concentration between 2E17 to 2E18/cm³ immediate below the Schottky contact metal in a P-type epitaxial layer between said plurality of doped JBS regions.

21. The method of claim 12 further comprising:
depositing a narrow bandgap layer comprising a silicon rich SiGe having a layer thickness approximately 200 Å immediate below the Schottky contact metal in said epitaxial layer between said plurality of doped JBS regions.
